(19) United States
(12) Patent Application Publication
(10) Pub. No.: US 2006/0157709 A1
(43) Pub. Date: Jul. 20, 2006

(54) Thin film transistor

(75) Inventor: Peter W. Green, Reigate (GB)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., Eindhoven (NL)

(21) Appl. No.: 10/562,293

(22) PCT Filed: Apr. 29, 2002
(86) PCT No.: PCT/IB03/03477

§ 371 Date: Dec. 22, 2005

(30) Foreign Application Priority Data
Aug. 20, 2002 (GB) 0219471.0

(51) Int. Cl. H01L 29/04

(52) U.S. Cl. 257/72; 438/149; 257/E27.112

(57) ABSTRACT

A method of fabricating a TFT comprises: etching a base layer structure (9) on a substrate (1) so as to form a gate (4) with inclined side edges (4a, 4b) that extend towards an apex region (12) with a tip (13) of a radius of a few nanometers, depositing an amorphous silicon channel layer (6) over the inclined side edges and the apex region, depositing a metal layer (8) over the channel layer so as to cover the apex region and the side edges, applying a layer of masking material (14) over the conductive material and selectively etching it so that the metal layer (8) in the apex region protrudes through and upstands from the masking material, and selectively etching the metal (8) that protrudes through the masking material (14) in the apex region such as to provide separate, self aligned source and drain regions (8a, 8b) overlying the inclined edges with a short channel (L) between them.

This invention relates to fabricating a thin film transistor (TFT) which may be used for example in an active matrix liquid crystal display (AMLCD) or other flat panel display.

As well known in the art, TFTs are employed in liquid crystal and other flat panel displays to control or sense the state of each pixel of the display. They may be fabricated on inexpensive insulating substrates such as glass or plastics material, utilising amorphous or polycrystalline semiconductor films, as described for example in U.S. Pat. No. 5,130,829.

TFTs are formed by the successive deposition of layers of different materials and conventionally, a generally horizontally disposed transistor may be produced that has a channel length defined by a photolithographic process. A shorter channel length is generally preferable since it reduces stray capacitances and increases the aperture ratio of the display.

Vertical TFTs can be made with shorter channel lengths than produced by horizontal photolithography and etching. In the fabrication of a vertical TFT, the channel length is usually defined in a plane substantially perpendicular to the substrate. A gate may be formed on the substrate and an amorphous silicon layer may be deposited so as to extend from the upper surface of the gate, downwardly along one of its vertically extending side edges and horizontally across the substrate. The downwardly extending portion of the amorphous silicon layer provides a vertically extending channel and its portions that overlie the gate and the substrate may be annealed using an excimer laser, so as to provide source and drain regions at the ends of the channel. Reference is directed to M. Matsumura & A. Saitoh, MRS Symp. Proc. Vol. 467 (1997), p 821.

In alternative vertical TFT fabrication techniques, the vertical step provided by the gate may be used to prevent etching of materials as described by Uchida et al, Jap. Jrnl. Appl. Phys., 25, 9 Sep. 1986, pp L798-L800. The step provided by the gate can also be used to act as a shadow mask when depositing source and drain electrodes, as described in 700 IBM Technical Disclosure Bulletin 29 (1986) October, No. 5, NY, USA and Hansell et al, U.S. Pat. No. 4,633,284. However, problems may arise resulting from non-uniform process characteristics occurring during fabrication of the vertical step structure. A further disadvantage is that the source overlies the gate in close proximity, which results in a large parasitic capacitance that can degrade performance of the display, for example, by increasing the time constant required for charging the column to the correct voltage.

Another TFT is described in U.S. Pat. No. 5,340,758. In this configuration, a gate is initially provided on an insulating substrate, in the form of a mesa with a top surface from which oppositely disposed, inclined side edges extend downwardly towards the substrate. Layers which provide a channel are subsequently deposited over the gate region including the inclined side edges. A metalisation layer is then deposited over the resulting structure. The device is then planarised using a photoresist, which is then reduced down in thickness until it is level with the uppermost, flat surface of the deposited metalisation over the gate. This produces a window in the photoresist, which is then used as a self-aligned mask through which the metalisation layer is etched to form separate source and drain regions overlying the inclined surfaces of the gate.

A problem with this device is that it has a significant horizontal extent, which limits the degree of miniaturisation that can be achieved.

It is an object of the present invention to an improved TFT fabrication process that allows improved, short channel lengths to be achieved. According to the invention there is provided a method of fabricating a TFT comprising: etching a base layer structure on a substrate so as to form a gate with inclined side edges that extend towards an apex region, depositing material to form a channel layer over the inclined side edges and the apex region, depositing conductive material over the channel layer so as to cover the apex region and the side edges, applying a layer of masking material over the conductive material, such that the conductive material in the apex region protrudes through and upstands from the masking material, and selectively etching the conductive material that protrudes through the masking material in the apex region such as to provide separate source and drain regions overlying the inclined edges.

By protruding the conductive material through the resist in the apex region, it can be etched in a manner to achieve an improved, very short channel length.

In accordance with the invention, the etching of the base layer structure may be carried out such that a tip is formed in the apex region, having a radius of a few nanometres. The etching may produce side edges that are inclined at angles of less than 90 degrees.

The invention also provides a TFT comprising a substrate, a gate overlying the substrate and having side edges inclined towards one another, a channel region overlying the gate, and source and drain regions overlying said side edges respectively, wherein the gate has been formed on the substrate by an etching process that involved formation of a tip in an apex region between the side edges of a radius of a few nanometres.

The tip may have been removed before the channel region was applied or a so-called blunted tip may be formed in the same way as the sharp tip but with a reduced etch time so that a blunt tip is formed in the apex region.

The gate may be overlaid by a layer of insulating material, with the channel layer overlying the insulating material, a layer of doped semiconductor material overlying the channel layer, and a layer of conductive material from which said source and drain regions have been formed, overlying the doped semiconductor material.

The channel region may comprise amorphous silicon, the insulating layer may comprise silicon nitride and the doped semiconductor layer may comprise n-doped silicon.

In order that the invention may be more fully understood embodiments thereof will now be described with reference to the accompanying drawings in which:

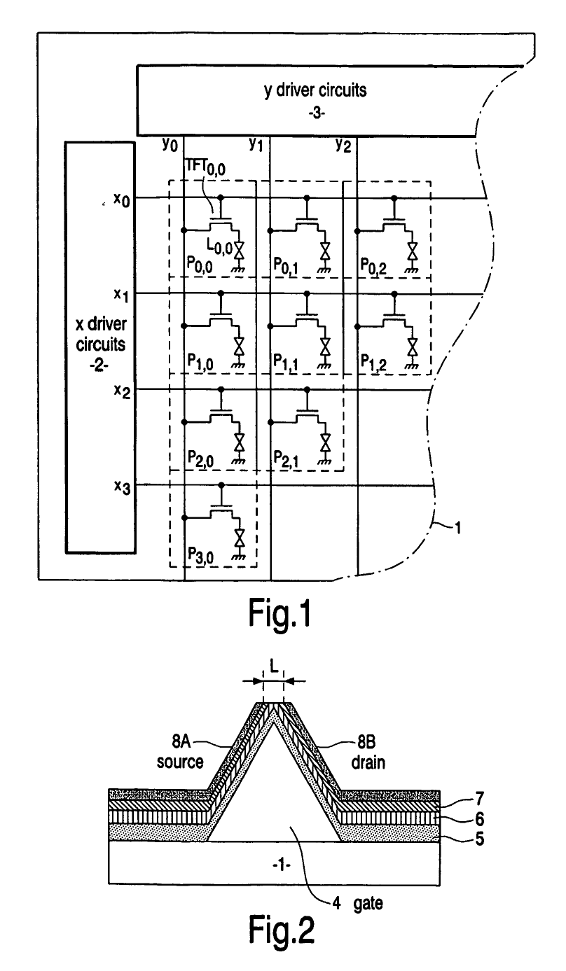

FIG. 1 is a schematic illustration of a AMLCD incorporating TFTs in accordance with the invention;

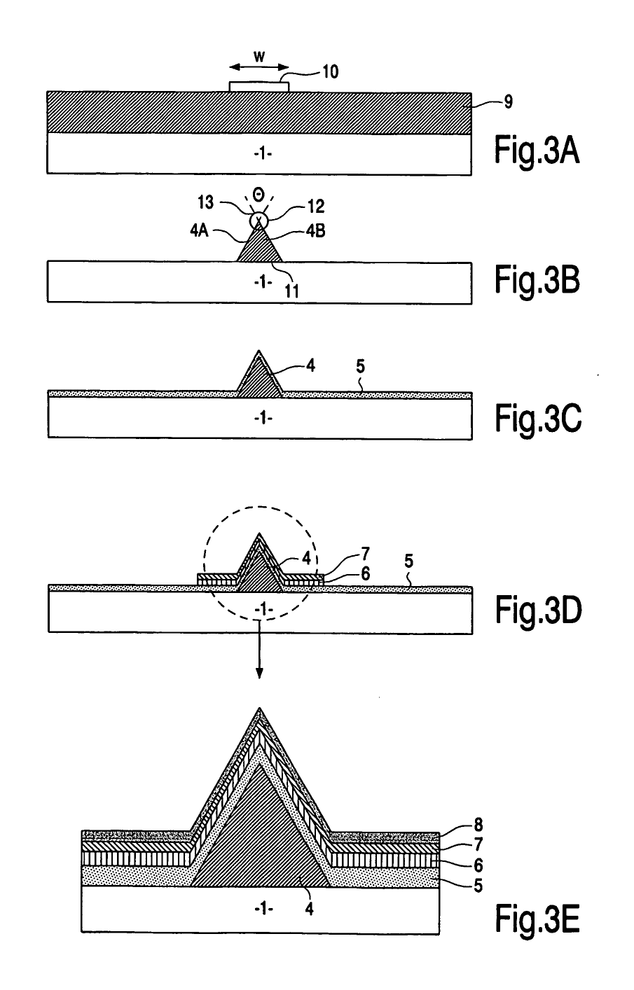

FIG. 2 is a cross sectional view of a TFT in accordance with the invention;

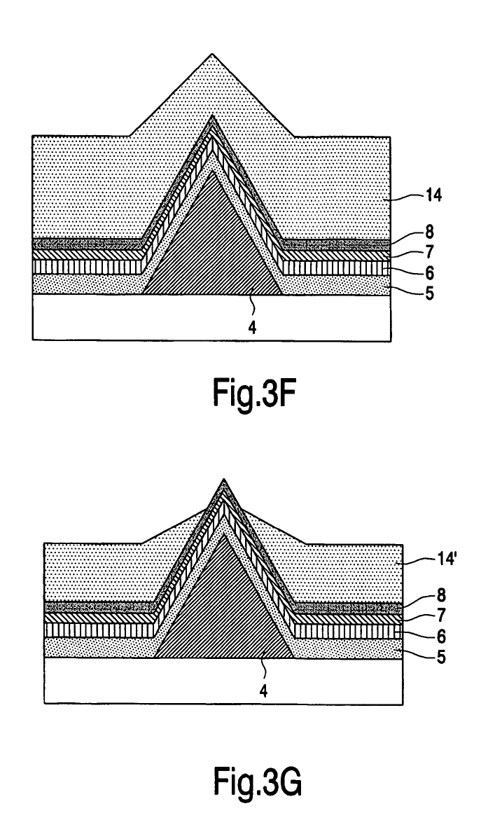

FIGS. 3A-1 illustrate a series of process steps for fabricating the TFT shown in FIG. 2;

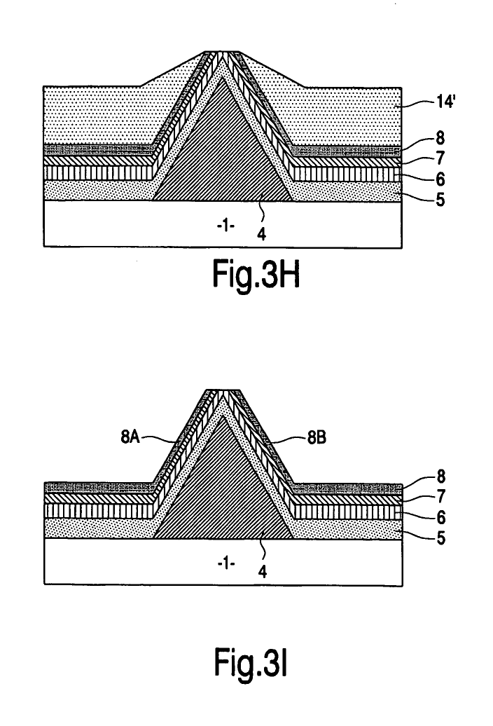

FIG. 4 is a schematic perspective view of the TFT fabricated by the process described with reference to FIG. 3;

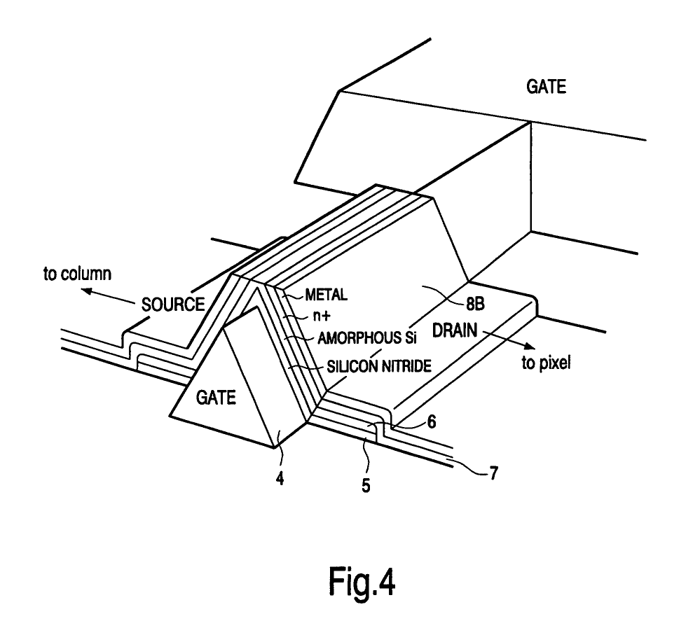

FIG. 5 is a schematic cross section of a variant of the TFT shown in FIG. 2; and

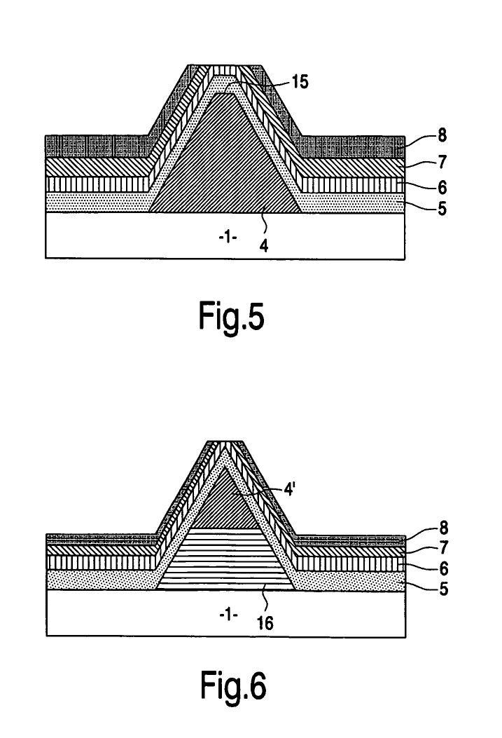

FIG. 6 is a schematic sectional view of another variant of the TFT.

Referring to FIG. 1, an AMLCD panel is formed on an electrically insulating substrate 1 that may be optically transparent, on which an active switching matrix of LCD pixels P is provided, in a manner well known per se in the art. Reference is directed to our EP-A-0 629 003. The substrate may also be semiconductive e.g. for a liquid crystal on silicon display, or conductive with an insulating layer beneath the TFTs and other conductive elements to prevent shorting. The pixels P_{x,y} are arranged in a rectangular x, y array and are operated by x and y driver circuits 2, 3.

Considering the pixel P_{0,0} by way of example, it includes a liquid crystal display element L_{0,0} which is switched between different optical transmisivities by means of TFT_{0,0} that has its gate connected to drive line x₀ and its source coupled to driver line y₀. By applying suitable voltages to the lines x₀, y₀, transistor TFT_{0,0} can be switched on and off and thereby control the operation of the LCD element L_{0,0}. It will be understood that each of the pixels P of the display is of a similar construction and that the pixels can be scanned row by row on operation of the x and y driver circuits 2, 3 in a manner well known per se.

FIG. 2 illustrates in transverse section an example of a TFT in accordance with the invention which may be used for the pixels P shown in FIG. 1. The TFT comprises a conductive gate region 4 formed on the substrate 1. The gate region 4 comprises a sharply pointed ridge which is triangular in cross section as shown in FIG. 2. A gate insulating layer 5 is deposited over the gate 4, which may comprise silicon nitride. Amorphous silicon layer 6 overlays the gate insulator 5, to form the channel of the transistor. An n⁺-doped region 7 overlays the amorphous silicon 6 and metallic source and drain electrodes 8a, 8b overlie the n-doped silicon layer 7. The transistor has a channel length L of the order of 20-40 nanometers. This value will also depend on the thickness of the deposited materials, tip sharpness and other factors evident to those skilled in the art.

A method of fabricating the TFT will now be described with reference FIG. 3. As shown in FIG. 3A, a base layer structure 9, 10 is applied to the substrate 1 for the purpose of forming the gate 4 shown in FIG. 2. The base layer structure comprises a layer 9 of conductive material overlaid by photoresist 10. The conductive material 9 may comprise a metal layer 9 for example Al, an Al alloy such as Al(1% Ti), Cr or Ta and may be deposited to a thickness of ˜1 to 2 microns. The thickness will depend on the resistance of row line required (as well as the tip height required). The larger the display the lower the row line resistance should be.

The photoresist 10 is patterned by conventional photolithographic techniques to form a rectangular pad 10 in the region where the gate 4 is to be formed. An example of the width dimension w shown in FIG. 3A of the rectangular region of photoresist 10, is 0.5-2 microns and it's length (perpendicular to the plane of the sectional view of FIG. 3A) is selected to provide a current charging path sufficient to operate the LCD pixel connected to it e.g. 5 microns.

The metal layer 9 is then etched and removed, except in the region of the photoresist 10 where the metal 9 is etched to form a sharply pointed structure shown in FIG. 3B, which acts as the gate 4. The formation of the sharply pointed structure may occur when using an isotropic etch but preferably the etching conditions are tailored so that the lateral etching rate is slower than the downward etching rate i.e. the etching process is anisotropic. For an Al (or Al alloy) layer 10, a wet etch can be used, for example orthophosphoric, nitric and acetic acids and water e.g. in the ratio ˜20:1:1:2 at a temperature of 40° C. Alternatively, a dry etch can be carried out e.g. Cl₂ & BCl₃ in the ratio of 1 to 4. The triangular sectioned structure 4 has a rectangular base 11 dimension of 1 to 2 microns, with opposed, inclined side edges 4a, 4b which extend to an apex region 12 that includes tip 13 of a radius of a few nanometres. The angle subtended between the inclined side edges 4a, 4b is less than 90° and typically in a range of 30° to 60°.

Then, as shown in FIG. 3B, the gate dielectric 5 is applied, in the form of a layer of silicon nitride, to a thickness of 40 to 200 nanometers.

Referring to FIG. 3C, the intrinsic amorphous silicon layer 6 used to form the channel of the transistor, is deposited by conventional CVD techniques to a thickness of 40 to 200 nanometers. Then, the n⁺-doped silicon layer 7 is applied by CVD to a thickness of 40 to 100 nanometers.

Then, as shown in FIG. 3E, metal layer 8 is applied to a thickness of 0.25 to 1 microns by CVD or sputtering. Suitable materials for the layer 8 are Al, Al(1% Ti), Cr, Mo and Ta. The layer 8 is deposited as a continuous layer extending over the inclined side edges 4a, 4b of the gate region 4 and a process is thereafter carried out to separate the continuous layer 8 into individual electrodes that form the source and drain 8a, 8b for the individual transistor. This involves a conventional photolithographic patterning of the layer 8 to define the lateral extent of the source and drain electrodes and also their connection to the individual driver lines x, y shown in FIG. 1, which may also be deposited and patterned as a part of this step.

Also, in accordance with the invention, a process is carried out to open the channel L shown in FIG. 2, between the source and drain electrodes 8a, 8b. This will now be described in more detail.

Referring to FIG. 3F, a photoresist 14 is spun onto the structure and then etched back using for example, an oxygen plasma to reveal the apex region 12, as shown in FIG. 3G. The exposed apex region 12 thus extends through and upstands from the surrounding photoresist 14′. Alternatively, it would be possible to flood the entire structure shown in FIG. 3F with UV light so that on developing the thereby exposed photoresist layer 14, the shallower region over the apex region is removed to reveal the tip, but leaving the bulk of the photoresist covering the sample as shown in FIG. 3G.

Thereafter, as shown in FIG. 3H, the apex region 12 is etched away so as to successively remove the exposed portion of layers 8, 7 and part of layer 6, so as to form the individual source and drain electrodes 8a, 8b and a channel region in the amorphous silicon layer 6 between them. This can be carried out using a dry etch on the amorphous Si e.g HCl & SF₆ in a ratio of 4:1.

The process has the advantage that the source and drain electrodes 8a, 8b are formed by a self-aligned etching process that does not require registry of a further photomask.

The remaining photoresist 14 is then removed so as to produce the TFT structure of FIG. 3H, which corresponds to the configuration of FIG. 2.

The resulting structure is shown in schematic perspective view in FIG. 4, from which it can be seen that the gate extends as a ridge structure with the source and drain regions 8a and 8b formed on its inclined side edges.

The resulting channel length of the TFT is a function of a number of factors. One of the most significant of these is the depth of photoresist removal over the apex region i.e. the amount of photoresist removed between the configuration of FIG. 3F and FIG. 3G.

Various modifications to the described TFT lie within the scope of the invention. For example, as shown in FIG. 5, the gate region 4 may be formed so that its tip 13 is blunted prior to the deposition of layers 5, 6, 7 and 8. Here it is likely that the so-called blunted tip is formed in the same way as the sharp tip. However, the etch time is reduced so that the sharp tip is not formed. The blunting may alternatively be carried out by selective etching to provide a flat top region 15. This gives rise to a longer channel length L as compared with the device of FIG. 2. Also, it gives rise to a more uniform electrical field in the channel region L during operation as compared with the sharp tip shown in FIG. 2.

Advantageously, the amorphous silicon layer 6 may have a low mobility, for example less than 0.2 cm²/Vs. The term “mobility” refers to the field effect mobility of the amorphous silicon in the channel region of the TFT excluding the effect of any contact resistance within the TFT. Benefits of having a channel region with a low mobility are discussed in WO 02/091475 to which reference is invited. In brief, these benefits include the reduction of leakage current. The reduction in switching speed, which results from the use of a semiconductor material having a low mobility, is out-weighed by the increase resulting from the short channel lengths achieved by the invention.

In another modification shown in FIG. 6, the triangular sectioned is region that provides the gate is made up of a metallic region 4′ that overlies an insulating region 16. This may be formed by configuring the initial base layer structure such that the metallic layer 9 shown in FIG. 3A is underlaid by an insulating layer (not shown) so that when the structure is etched, the region 16 is formed from the insulating layer underlying the gate 4′ shown in FIG. 6. In this way, the gate to drain/source parasitic capacitance of the TFT can be reduced as compared with the devices shown in FIGS. 2 and 4.

TFTs in accordance with the invention have particular application to AMLCD devices, particularly for LC-TV applications. The fabrication technique according to the invention has the advantage that only the initial step of FIG. 3A that defines the gate position, is required to be carried out by photolithography and all the remaining steps that define the relationship of the source, drain, gate and channel are achieved by self-aligning techniques.

From reading the present disclosure, other variations and modifications will be apparent to persons skilled in the art. Such variations and modifications may involve equivalent and other features which are already known in the design, manufacture and use of electronic devices comprising TFTs and other semiconductor devices and component parts thereof and which may be used instead of or in addition to features already described herein.

1. A method of fabricating a TFT comprising: etching a base layer structure on a substrate so as to form a gate with inclined side edges that extend towards an apex region, depositing material to form a channel layer over the inclined side edges and the apex region, depositing conductive material over the channel layer so as to cover the apex region and the side edges, applying a layer of masking material over the conductive material, such that the conductive material in the apex region protrudes through and upstands from the masking material, and selectively etching the conductive material that protrudes through the masking material in the apex region such as to provide separate source and drain regionsoverlying the inclined edges.

2. A method according to claim 1 including applying the masking material to cover the apex region and then selectively removing the masking material so that the conductive material in the apex region protrudes through and upstands from the masking material.

3. A method according to claim 2 wherein the masking material comprises a photo resist (14), and including spinning the substrate to cover the conductive material with the photo resist.

4. A method according to claim 3 including selectively etching the photo resist to expose the apex region.

5. A method according to claim 1 wherein the etching of the base layer structure is carried out such that a tip is formed in the apex region, having a radius of a few nanometres.

6. A method of fabricating a TFT comprising: etching a base layer structure on a substrate so as to form a base region with inclined side edges which extend towards an apex region that includes a tip of a radius of a few nanometres, depositing material to form a channel layer over apex region and selectively etching the conductive material in the apex region such as to provide separate source and drain regions overlying the inclined edges, and providing a gate in said base region.

7. A method according to claim 5 including removing the tip before depositing the channel layer.

8. A method according to claim 1 including depositing an electrically insulating layer over the gate, and depositing the channel layer over the insulating layer.

9. A method according to claim 8 including depositing a doped semiconductor layer (7) over the channel layer, and depositing the conductive material in a layer over the doped semiconductor layer.

10. A method according to claim 1 including carrying out the etching of the base layer structure (such that the side edges are inclined at angle of less than 90 degrees.

11. A method according to claim 1 wherein the etching of the base layer structure includes masking a region of the base layer structure, and etching the base layer structure such that a ridge structure is formed from the base layer structure in the masked region.

12. A method according to claim 1 wherein the base layer structure comprises a layer of conductive material overlying a layer of insulating material and the etching of the base layer structure is carried out so as to form a ridge structure from the base layer structure.

13. A TFT fabricated by a method as claimed in claim 1.

14. A device including a TFT according to claim 13.

15. An AMLCD including a plurality of TFTs fabricated by a method as claimed in claim 1.

16. A TFT comprising a substrate a gate overlying the substrate and having side edges inclined towards one another, a channel region overlying the gate, and source and drain regions overlying said side edges respectively, wherein the gate has been formed on the substrate by an etching process that involved formation of a tip in an apex region between the side edges of a radius of a few nanometres.

17. A TFT according to claim 16 wherein the tip (13) was removed before the channel region was applied.

18. A TFT according to claim 16 wherein the gate is overlaid by a layer of insulating material, the channel region overlies the insulating material, a layer of doped semiconductor material overlies the channel region, and a layer of conductive material from which said source and drain regions have been formed, overlies the doped semiconductor material.

19. A TFT according to claim 16 wherein the channel region (6) comprises intrinsic amorphous silicon.

20. A TFT according to claim 18 wherein the insulating layer comprises (5) silicon nitride.

21. A TFT according to claim 18 wherein the doped semiconductor material (7) comprises n doped silicon.
